(19) United States
(12) Patent Application Publication
(10) Pub. No.: US 2014/0169102 A1
(43) Pub. Date: Jun. 19, 2014

(54) LOG-LIKELIHOOD RATIO AND LUMPED LOG-LIKELIHOOD RATIO GENERATION FOR DATA STORAGE SYSTEMS

(71) Applicant: Western Digital Technologies, Inc., (US)

(72) Inventors: YONGKE SUN, PLEASANTON, CA (US); DENGTAO ZHAO, SANTA CLARA, CA (US); JUI-YAO YANG, SAN JOSE, CA (US)

(73) Assignee: WESTERN DIGITAL TECHNOLOGIES, INC., Irvine, CA (US)

(21) Appl. No.: 13/720,591

(22) Filed: Dec. 19, 2012

(51) Int. Cl. G11C 16/10; G11C 16/26

(52) U.S. Cl. CPC G11C 16/10; G11C 16/26
USPC 365/185.24

(57) ABSTRACT

An error management system for a data storage device can generate soft-decision log-likelihood ratios (LLRs) for upper and lower pages of memory cells in MLC solid-state media. Disclosed are systems and methods for generating lumped-LLR for upper pages, wherein at least some voltage threshold reads are linked together in order to reduce the number of reads. Efficiency and reliability are thereby improved.

### BACKGROUND

1. Technical Field

This disclosure relates to data storage systems. More particularly, the disclosure relates to systems and methods for generating log-likelihood ratios for data storage systems.

2. Description of the Related Art

Soft-decision low-density parity-check code (LDPC) error code correction (ECC) can improve the reliability of a data storage system and reduce the number of data errors. Log-likelihood ratios (LLRs) are commonly used as the inputs for soft-decision LDPC engines. Data storage systems that use multi-level-per-cell (MLC) flash memories as data storage media can use LLR calculations for reading memory cells when hard-decision LDPC is insufficient to decode the originally-stored data.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 is a block diagram illustrating a combination of a host system with storage subsystem including an error management module.

FIG. 2 is a graph showing a probability distribution of cells in a non-volatile memory array according to one embodiment.

FIG. 3 is a graph showing a probability distribution of cells in a non-volatile memory array according to another embodiment.

FIG. 4 is a flow diagram showing an upper page LLR generation process using lower page readback according to one embodiment.

FIG. 5A is a graph showing a probability distribution of cells having upper page values that can be lumped according to one embodiment.

FIG. 5B is a graph showing a probability distribution of cells having lumped upper pages according to one embodiment.

FIG. 6 is a flow diagram showing an embodiment of a process for upper page lumped-LLR generation.

FIGS. 7A-7C are graphs showing a probability distribution of cells programmed according to a three-bit encoding scheme according to one embodiment.

FIG. 7D is a flow diagram showing an embodiment of a process for upper page lumped-LLR generation in a three-bit encoding scheme according to one embodiment.

### DETAILED DESCRIPTION

While certain embodiments are described, these embodiments are presented by way of example only, and are not intended to limit the scope of protection. Indeed, the novel methods and systems described herein may be embodied in a variety of other forms. Furthermore, various omissions, substitutions and changes in the form of the methods and systems described herein may be made without departing from the scope of protection.

### Overview

Data storage cells in MLC flash memory can have distinct threshold voltage distribution (Vₜ) levels, corresponding to different memory states. Voltage read levels can advantageously be set to values in the margins between memory states. According to their charge level, memory cells store different binary data representing user data. For example, each cell generally falls into one of the memory states, represented by associated data bits. Performing cell reads at the various read levels can provide hard-decision input data for identifying the memory states to which certain cells are connected with when the distributions for different states are tight and there is no overlap between them.

Over time, and as a result of various physical conditions and wear from repeated program/erase (P/E) cycles, the margins between the various distribution levels may be reduced, so that voltage distributions overlap to some extent. Such reduction in a read margin may be due to a number of factors, such as loss of charge due to flash cell oxide degradation, over-programming caused by erratic program steps, programming of adjacent erased cells due to heavy reads or writes in the locality of the cell (or write disturbs), and/or other factors. When voltage distributions overlap, hard-decision inputs may not provide enough information to decode the original data.

Soft-decision inputs, such as log-likelihood ratios (LLRs), can enhance the probability of successful decoding in certain situations. However, calculating LLRs for MLC cells can be computationally expensive when certain methods are implemented due to the need to read lower and upper pages of a non-volatile memory array. Embodiments disclosed herein provide systems and methods for lumped-LLR generation in data storage systems which use MLC non-volatile memory arrays as data storage media, which can reduce the number of reads required compared to certain other techniques. This can improve efficiency and reliability.

As used in this application, “non-volatile memory” may refer to solid-state memory such as NAND flash. However, the systems and methods of this disclosure may also be useful in more conventional hard drives and hybrid drives including both solid-state and hard drive components. Solid-state memory may comprise a wide variety of technologies, such as flash integrated circuits, Phase Change Memory (PC-RAM or PRAM), Programmable Metallization Cell RAM (PMC-RAM or PMCm), Ovonic Unified Memory (OUM), Resistance RAM (RRAM), NAND memory, NOR memory, EEPROM, Ferroelectric Memory (FeRAM), MRAM, or other discrete NVM (non-volatile memory) chips. The non-volatile memory arrays or solid-state storage devices may be physically divided into planes, blocks, pages, and sectors, as is known in the art. Other forms of storage (e.g., battery backed-up volatile DRAM or SRAM devices, magnetic disk drives, etc.) may additionally or alternatively be used.

### System Overview

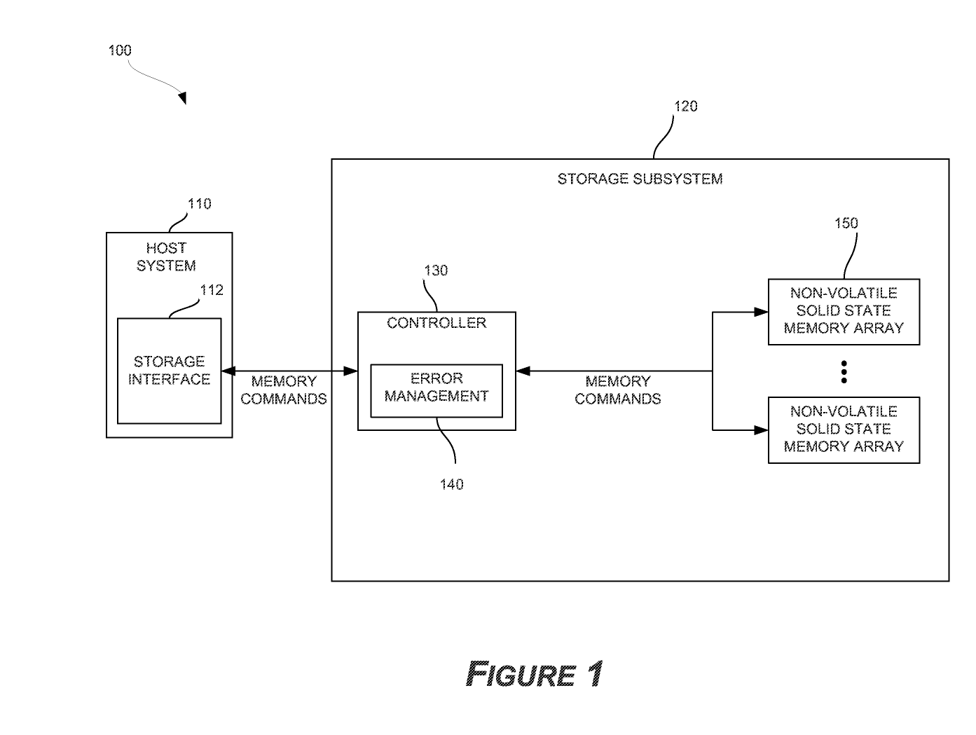

FIG. 1 is a block diagram illustrating a combination 100 of a host system with storage subsystem including an error management module 140. As shown, a storage subsystem 120 includes a controller 130, which in turn includes an error management module 140. In certain embodiments, the error management module 140 is configured to detect and correct certain kinds of internal data corruption of one or more non-volatile solid-state memory arrays 150. In one embodiment, the error management module is configured to generate LLRs for MLC cells of the memory array 150 for soft-decision error correction. In certain embodiments, the controller 130 is configured to receive memory access commands from a storage interface (e.g., driver) 112 residing on a host system 110 and execute commands in response to such host-issued memory commands in the non-volatile solid-state memory arrays 150. Data may be accessed/transferred based on those commands.

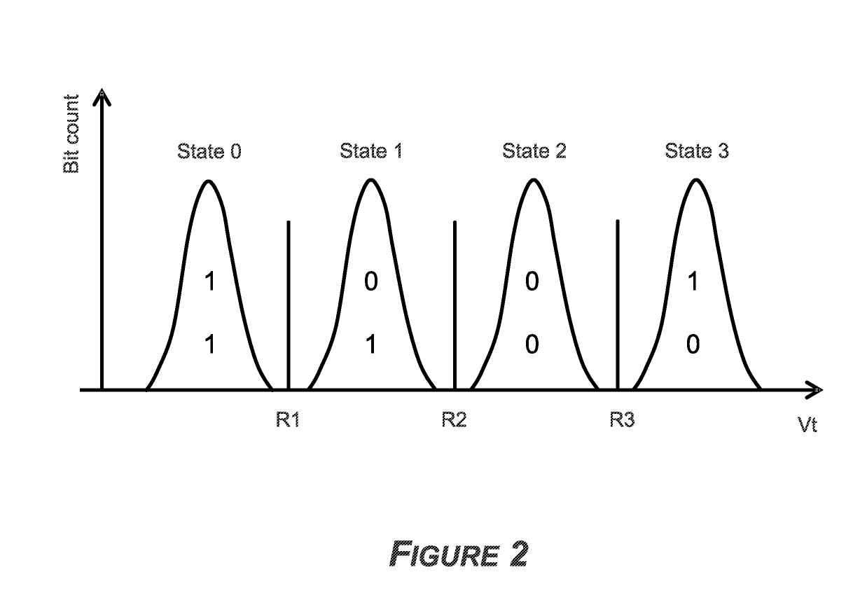

FIG. 2 is a graph showing a probability distribution of cells in a non-volatile memory array according to one embodiment. Flash memory, such as multi-level cell (MLC) NAND flash memory, may store two or more bits of information per cell. While certain embodiments disclosed herein are described in the context of MLCs, it should be understood that the concepts disclosed herein may be compatible with single level cell (SLC), three-level cell (TLC) technology (a type of MLC NAND), and/or other types of technology. Data is generally stored in MLC NAND flash memory in binary format. For example, two-bit-per-cell memory cells can have 4 distinct threshold voltage (Vₜ) levels, and 3-bit-per-cell memory cells can have 8 distinct Vₜ levels, and so on. According to their Vₜ, and the coding associated with their Vₜ, memory cells store different binary bits.

The horizontal axis depicted in FIG. 2 represents cell voltage level. The vertical axis represents the number of cells that have the corresponding voltage values. Thus, the four distribution curves represent the number of cells, broken down by the four distributions, which have the corresponding voltage values. As shown, the voltage distribution of the memory cells may include a plurality of distinct levels, or states (e.g., States 0-3 in this example 2-bit-per cell MLC configuration, as shown). Read reference values (i.e., voltage threshold levels R1-R3) may be placed between these levels. The gap between the levels (i.e., margin between programmed states), in which the read voltage references may advantageously be positioned in certain embodiments, is referred to as “read margin.” Over time, and as a result of various physical conditions and wear, for example from being subjected to repeated P/E cycles, the read margins between the various distribution levels may be reduced, resulting in both data retention problems and higher read errors beyond certain limits. Such reduction in read margin may be due to a number of factors, such as loss of charge due to flash cell oxide degradation, over-programming caused by erratic program steps, programming of adjacent erased cells due to heavy reads or writes in the locality of the cell (or write disturbs), and/or other factors.

While the diagram of FIG. 2 illustrates a Vₜ distribution for 2-bit-per-cell flash memories, embodiments and features disclosed herein may be applicable to other types of coding schemes. With respect to the embodiment of FIG. 2, the coding for States 0-3 can be, for example, “11,” “01,” “00,” and “10,” or any other coding. Each cell may generally fall into one of the illustrated states and correspondingly represents two bits. For one word line (WL), which can be connected to tens of thousands of cells in a NAND array, the lower digit of the cells may be referred to as the “lower page,” and the upper digit may be referred to as the “upper page.” For 3-bit-per-cell flash memories, there may also be intermediate digits, which may be referred to as “middle pages.” Reading voltage levels and operations are dependent on the coding of these states. For example, for the coding as shown in FIG. 2 for the 2-bit-per-cell flash memories, one read at R2 may be required to read out the lower page, and two reads at both R1 and R3 may be required to read out the upper page. As shown in the distribution of FIG. 2, these reading voltages may be selected between state distributions in the case where the distributions for different states are narrow so that there is no overlap between them.

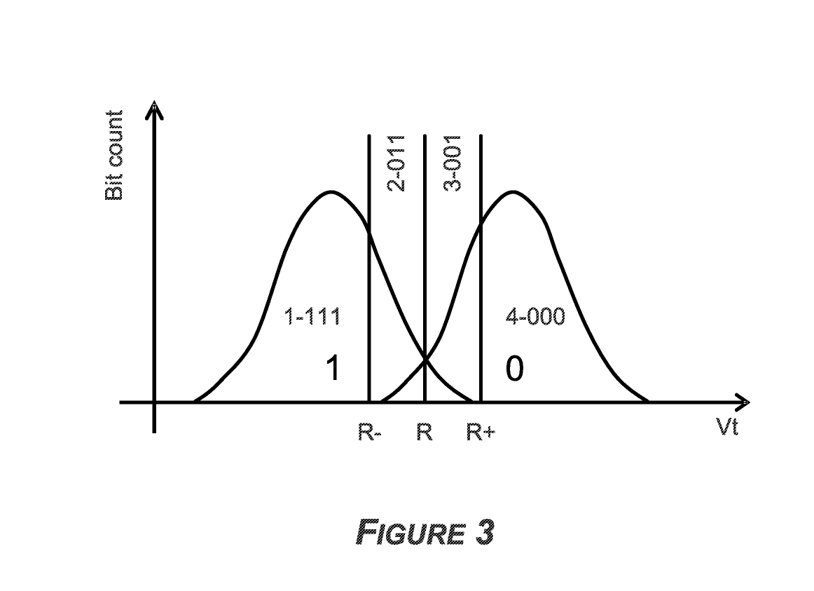

FIG. 3 is a graph showing a probability distribution of cells in a non-volatile memory array according to another embodiment. As discussed above, due to the memory wearing out, loss of data retention, and the like, the states of a voltage distribution can widen and overlap. Reading at preset read voltages may not be enough to decode the original data, even with utilizing a suitable ECC scheme, such as, hard-decision LDPC. In such situations, soft-decision inputs may be desirable for an LDPC engine, since soft-decision LDPC can provide additional input to the LDPC engine than just utilizing a hard-decision LDPC.

In one embodiment, for NAND flash memories soft-decision inputs can be LLRs. The LLR generation algorithm may involve multiple reads with different reading voltages, as shown in FIG. 3, where three reads are involved with reading voltages at R, R−, and R+. These three reading voltages divide the distribution shown at FIG. 3 into four zones (e.g., zones 1-4, from left to right). Although three reading voltages are illustrated in FIG. 3, certain embodiments may include more than three reading voltages, wherein the distribution may be divided into more than four zones. For example, 4, 5, 6, or more reads may be taken in association with a junction between voltage states. Flash cells having charge levels in the different zones may return different values corresponding to the respective zone. For example, in certain embodiments, flash cells read with Vₜ set within zone 1 return “1” for each of the three reads (“111”); cells read with Vₜ set within zone 2 return “011”; cells read with Vₜ set within zone 3 return “001”; and cells read with Vₜ set within zone 4 returns (“000”). If the data are known, the LLRs for these 4 groups of number combination may be obtained. For example, if there are a total of N cells in zone 1, among which the real values of m cells are 0, LLR can be determined using: LLR(111)=log(m/N-m). Although FIG. 3 shows three reads and four zones, more reads and zones are possible in other embodiments, and the LLRs may be generated in a similar manner to that described above.

In certain embodiments, LLRs are generated based on known data (e.g., stored in predetermined memory pages). In other embodiments, LLRs are generated based on data that can be decoded using a hard-decision ECC scheme. In some embodiment, known data and/or hard-decodable data can be used. When hard-decision LDPC fails, the LLRs may be generated from a priori and/or other reference data and applied to data being currently read as soft-decision inputs in order to enhance the likelihood of successfully decoding the data. For example, during reading a page of memory, read errors are encountered and soft-decision data may be used for decoding data stored in the page.

### Lower Page LLR Generation

Example implementations described below are based on two-bit-per-cell flash memory. However, it should be understood that the features and embodiments described are not limited to two-bit-per-cell flash memory. In one embodiment, two-bit-per-cell flash memory may have two pages per WL. Because the reading algorithm may be different for lower pages and upper pages, the two cases can be treated separately.

For two-bit-per-cell flash memory with the coding shown in FIG. 2, any distribution overlaps between State 0 and State 1, or State 2 and State 3, do not generally cause errors with respect to the lower page. Thus, States 0 and 1 may be treated as a single state consisting of a pool of data having lower page values of “1,” and States 2 and 3 may be treated as a single state consisting of a pool of data having lower page values of “0.” Thus, for a lower page of the two-bit-per-cell flash memories, the distribution illustrated in FIG. 3 can be used. The LLRs for a lower page can then be generated in accordance with the above description of FIG. 3.

In certain embodiments, it may be desirable to select voltage threshold R at a position lying at or near the cross point of the two sections of the Vₜ distribution, as shown in FIG. 3. Furthermore, it may be desirable for R− and R+ to be positioned a distance from R that covers the overlap region. However, any suitable selection of read values may be used.

### Upper Page Lumped-LLR Generation

For two-bit-per-cell flash memory upper pages with the coding shown in FIG. 2, the LLR generation method described above for lower pages may no longer be effective. For example, for lower page reads, since the 0's and 1's are naturally divided into two pools according to their Vₜ, it is relatively straightforward to use multiple reads to obtain the LLRs. For upper pages, however, difficulties may arise for either R1 reads or R3 reads, since both reads may have overlapping 0's and 1's at least one side of the reading voltages. Therefore, the error management module 140 may not be able to determine which 0's or 1's are generated by either the R1 or R3 read. The value returned may be merely the final values obtained from the combination of the two reads, based on the control of a finite state machine inside the NAND memory array.

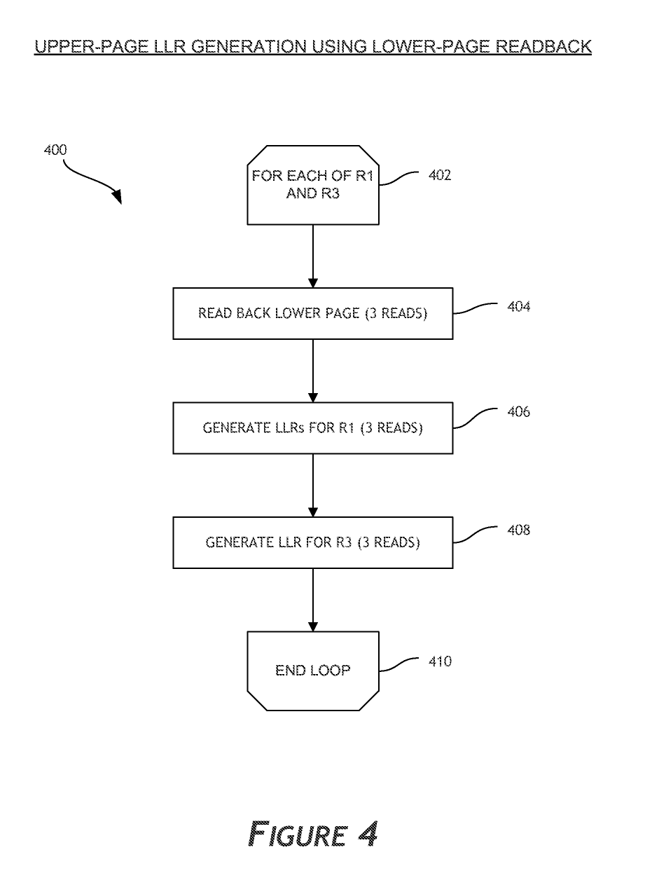

One way to distinguish between R1 and R3 according to an embodiment is to read back the corresponding lower page to discriminate between states when generating the LLRs for an upper page. FIG. 4 is a flow diagram showing an embodiment of an upper page lumped-LLR generation process 400 using lower page readback. The process 400 can be executed by the controller 130 and/or the error management module 140. For each R1 and R3, once the lower page is read back (in block 404), the process 400 transitions to blocks 406 and 408 where it generates LLRs for both R1 and R3 respectively. For example, for LLR generation for R1, 9 reads may be required, including 3 shifted voltage reads at R1, 3 reads for reading back the lower page, and 3 reads at R3. Similarly, 9 reads may be required to generate LLRs for R3 as well. Therefore, 18 reads may be required in total to generate the LLRs for the upper page, which may present a significant load on the system.

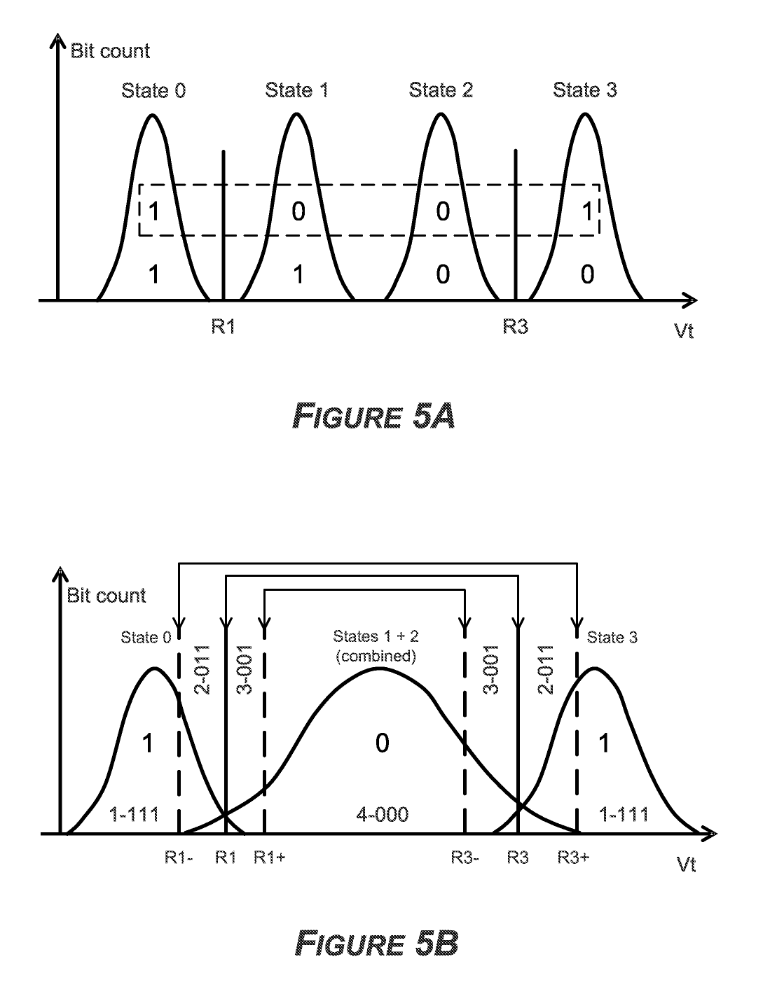

Certain embodiments disclosed herein provide methods for reducing the number of reads required for upper page LLR generation for both R1 and R3. FIG. 5A is a graph showing a probability distribution of cells having upper page values that can be lumped according to one embodiment. As illustrated in FIG. 5A, for an upper page, as highlighted by the dashed box, State 1 and State 2 can be considered as one pool containing all cells with a value of “0,” and lumped-LLR can be generated for both R1 and R3 read at the same time. Overlap between States 1 and 2, if there is any, does not affect the upper page read, since they are both coded as “0.” Therefore, for simplicity, States 1 and 2 can be considered as a single state consisting of the pool of “0's.” With this simplification, the number of read operations required to achieve the LLR generation can be reduced.

Since the system may not distinguish the states when “1'” is read back, States 0 and 3 may also be considered as a single state containing all the 1's. The distribution may be considered to “roll-over,” such that States 0 and 3 overlap. Therefore, similarly to the lower page read, R1 and R3 reads may be considered as a single interlocked read, and voltage bonding techniques (described below) may be used when taking the multiple reads. FIG. 5B is a graph showing a probability distribution of cells having lumped upper pages according to one embodiment. As an example, the following read levels may be lumped together: R1 and R3, R1+ and R3−, and R1− and R3+. In certain embodiments, the two reading levels for each pair have the same relative voltage shift. In certain embodiments, voltage shifts of the bonding voltage pairs are not the same. In the multiple read process to generate LLRs, R1 and R3 bonding pairs may be used to read the upper pages. Three reads, as described above, may take three pairs of reading voltages. As shown in FIG. 5B, read voltage bonding may divide the distribution into four zones (labeled 1, 2, 3, 4). As such, the upper page LLR generation may be like that for lower page LLR generation, but now the LLRs generated are not for a single reading voltage, but are the lumped-LLRs for both R1 and R3. Therefore, in certain embodiments, upper page LLRs may be generated using a total of six reads, as opposed to the 18 reads that may be required for the method described in FIG. 4 above.

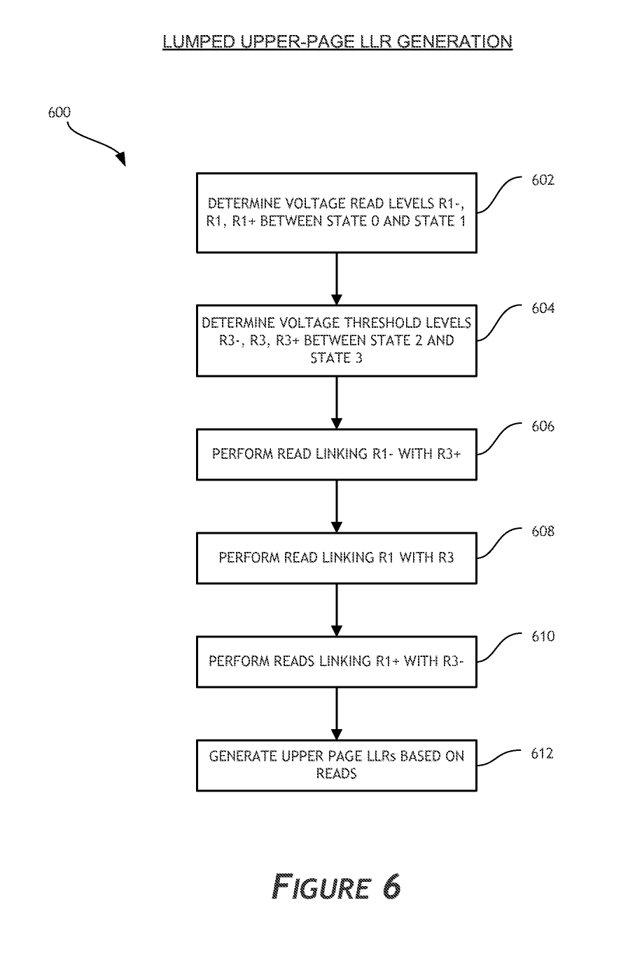

FIG. 6 is a flow diagram showing an embodiment of a process 600 for upper page lumped-LLR generation. The process 600 can be executed by the controller 130 and/or the error management module 140. The process 600 may include selecting voltage read levels between states having different upper page values. For example, for the scheme shown in FIG. 5B, voltage read levels, including shifted read levels, may be determined for R1 and R3, at blocks 602 and 604, respectively. The process 600 further includes linking pairs of voltage read levels, as discussed above. Blocks 606, 608, and 610 provide example pairs that may result in desirable zones in the distribution. The reads of the linked pairs are used to generate soft-decision LLRs for the upper pages of cells in MLC media.

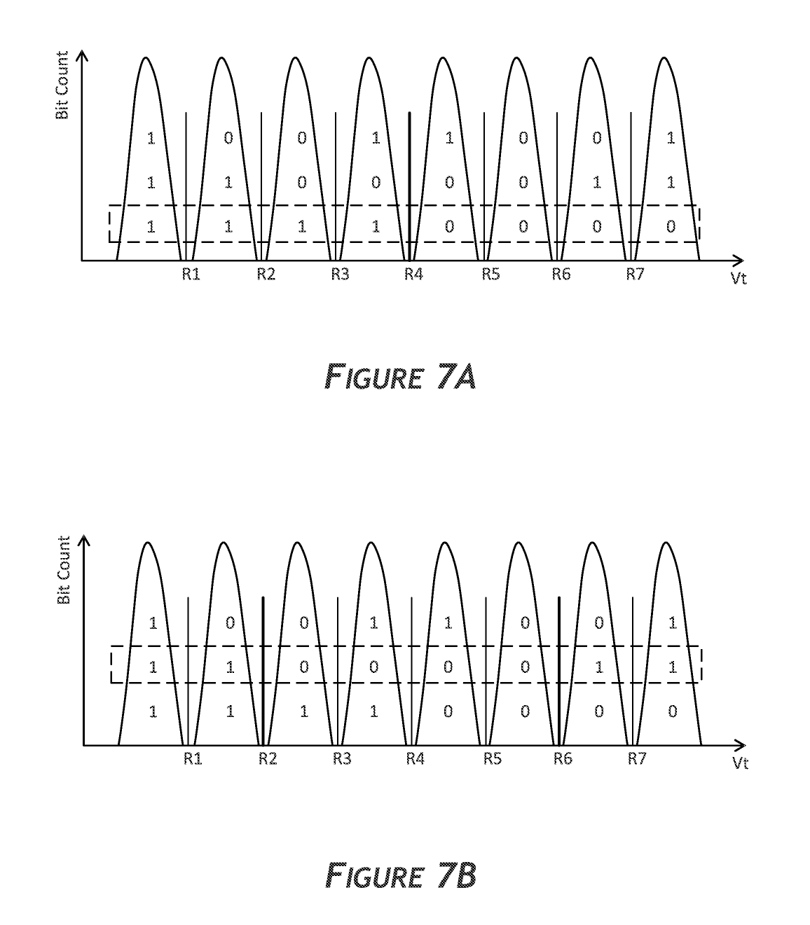

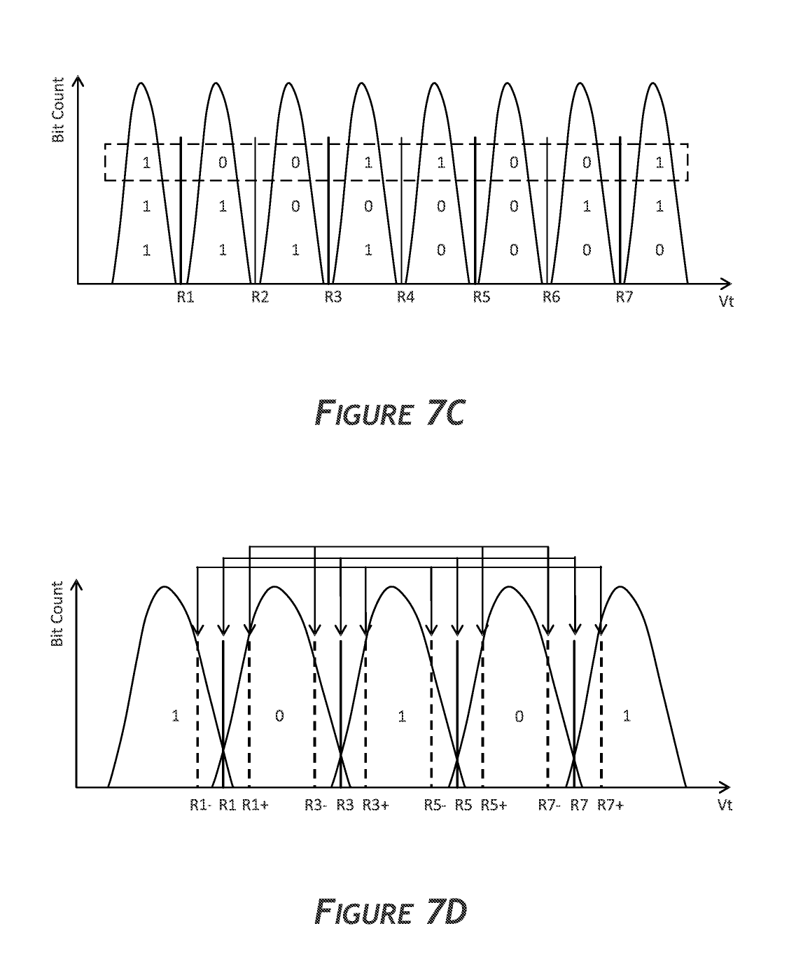

FIGS. 7A-7C are graphs showing a probability distribution of cells programmed according to a three-bit (TLC) encoding scheme according to one embodiment. As shown, in certain embodiments, lower page LLR generation may include reading at R4, similarly to the MLC embodiment described above. Middle page LLR generation may include reading at R2 and R6, similarly to MLC upper page LLR generation, discussed above. FIG. 7D is a flow diagram showing an embodiment of a process for upper page lumped-LLR generation in a TLC encoding scheme according to one embodiment. Upper page LLR generation of TLC may include reading according to the following groupings: R1, R3, R5 and R7; R1−, R3+, R5−, and R7+; R1, R3, R5 and R7; and R1+, R3−, R5+, and R7−. In the same manner as described above, the number of read operations required to generate LLRs can be reduced.

### Other Variations

The read levels, states, and coding schemes associated with voltage level distributions described herein, as well as variables and designations used to represent the same, are used for convenience only. As used in this application, “non-volatile memory” typically refers to solid-state memory such as, but not limited to, NAND flash. However, the systems and methods of this disclosure may also be useful in more conventional hard drives and hybrid hard drives including both solid-state and hard drive components. The solid-state storage devices (e.g., dies) may be physically divided into planes, blocks, pages, and sectors, as is known in the art. Other forms of storage (e.g., battery backed-up volatile DRAM or SRAM devices, magnetic disk drives, etc.) may additionally or alternatively be used.

Those skilled in the art will appreciate that in some embodiments, other types of data storage systems and/or data retention monitoring can be implemented. In addition, the actual steps taken in the processes shown in FIGS. 4 and 6 may differ from those shown in the figures. Depending on the embodiment, certain of the steps described above may be removed, others may be added. Accordingly, the scope of the present disclosure is intended to be defined only by reference to the appended claims.

While certain embodiments have been described, these embodiments have been presented by way of example only, and are not intended to limit the scope of protection. Indeed, the novel methods and systems described herein may be embodied in a variety of other forms. Furthermore, various omissions, substitutions and changes in the form of the methods and systems described herein may be made. The accompanying claims and their equivalents are intended to cover such forms or modifications as would fall within the scope and spirit of the protection. For example, the various components illustrated in the figures may be implemented as software and/or firmware on a processor, ASIC/FPGA, or dedicated hardware. Also, the features and attributes of the specific embodiments disclosed above may be combined in different ways to form additional embodiments, all of which fall within the scope of the present disclosure. Although the present disclosure provides certain preferred embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

What is claimed is:

1. A solid-state storage device comprising:
a non-volatile solid-state memory array comprising a plurality of non-volatile memory cells configured to store user data, the memory cells comprising a first page and a second page; and
a controller configured to determine log likelihood ratios (LLRs) corresponding to the first page of a memory cell of the plurality of memory cells by at least:
performing a first plurality of reads at a plurality of threshold voltages, wherein the plurality of threshold voltages divides a charge distribution spectrum associated with the cell into a plurality of zones; and
determining first page LLRs associated with the plurality of zones based at least in part on known data values and the first plurality of reads;
wherein the controller is further configured to determine LLRs corresponding to the second page of the memory cell by at least:
determining at least a first threshold voltage level R1−, second threshold voltage level R1, and third threshold voltage level R1+ associated with a first threshold voltage;
determining at least a first threshold voltage level R3−, second threshold voltage level R3, and third threshold voltage level R3+ associated with a second threshold voltage;
performing a second plurality of reads at the threshold voltage levels R1−, R1, R1+, R3−, R3, and R3+; and
determining second page LLRs based at least in part on the second plurality of reads and known data values.

2. The solid-state storage device of claim 1, wherein the second page LLRs are associated with a first lumped zone including voltage levels less than R1− and greater than R3+, a second lumped zone including voltage levels between R1− and R1 and between R3 and R3+, a third lumped zone including voltage levels between R1 and R1+ and between R3− and R3, and a fourth lumped zone including voltage levels between R1+ and R3−.

3. The solid-state storage device of claim 1, wherein the controller is configured to determine the second page LLRs without reading back one or more of the first plurality of reads.

4. The solid-state storage device of claim 1, wherein one or more of the first page LLRs or second page LLRs are used by the controller as inputs to a soft-decision low-density parity check (LDPC) engine.

5. The solid-state storage device of claim 1, wherein the memory cell is configured to store two bits of data.

6. The solid-state storage device of claim 1, wherein the solid-state memory array is a NAND flash memory array.

7. The solid-state storage device of claim 1, wherein the plurality of zones comprises four zones.

8. The solid-state storage device of claim 1, wherein the first page is a lower page and the second page is an upper page.

9. A method of determining log likelihood ratios (LLRs) in a non-volatile solid-state storage device that comprises a plurality of non-volatile memory cells configured to store user data, the memory cells comprising a first page and a second page, the method comprising:
determining LLRs corresponding to the first page of a memory cell of the plurality of memory cells by at least:
performing a first plurality of reads at a plurality of threshold voltages, wherein the plurality of threshold voltages divides a charge distribution spectrum associated with the cell into a plurality of zones; and
determining first page LLRs associated with the plurality of zones based at least in part on known data values and the first plurality of reads; and
determining LLRs corresponding to the second page of the memory cell by at least:
determining a first threshold voltage level R1−, second threshold voltage level R1, and third threshold voltage level R1+ associated with a first threshold voltage;
determining a first threshold voltage level R3−, second threshold voltage level R3, and third threshold voltage level R3+ associated with a second threshold voltage;
performing a second plurality of reads at the threshold voltage levels R1−, R1, R1+, R3−, R3, and R3+; and
determining second page LLRs based at least in part on the second plurality of reads.

10. The method of claim 9, wherein the second page LLRs are associated with a first lumped zone including voltage levels less than R1− and greater than R3+, a second lumped zone including voltage levels between R1− and R1 and between R3 and R3+, a third lumped zone including voltage levels between R1 and R1+ and between R3− and R3, and a fourth lumped zone including voltage levels between R1+ and R3−.

11. The method of claim 9, wherein determining the second page LLRs is performed without reading back one or more of the first plurality of reads.

12. The method of claim 9, further comprising providing one or more of the first page LLRs or second page LLRs as inputs to a soft-decision low-density parity check (LDPC) engine.

13. The method of claim 9, wherein the memory cell is configured to store two bits of data.

14. The method of claim 9, wherein the plurality of zones comprises four zones.

15. The method of claim 9, wherein the first page is a lower page and the second page is an upper page.

16. A solid-state storage device comprising:
a non-volatile solid-state memory array comprising a plurality of non-volatile memory cells configured to store user data, the memory cells comprising a first page and a second page; and
a controller configured to determine log likelihood ratios (LLRs) corresponding to the first page of a memory cell of the plurality of memory cells by at least:
performing a first plurality of reads at a plurality of threshold voltages, wherein the plurality of threshold voltages divides a charge distribution spectrum associated with the cell into a plurality of zones; and
determining first page LLRs associated with the plurality of zones based at least in part on known data values and the first plurality of reads;
wherein the controller is further configured to determine LLRs corresponding to the second page of the memory cell by at least:
determining at least a first voltage read level, a second voltage read level, and a third voltage read level associated with a first threshold voltage;
determining at least a fourth voltage read level, a fifth voltage read level, and a sixth voltage read level associated with a second threshold voltage;
performing a second plurality of reads at the first, second, third, fourth, fifth, and sixth voltage read levels; and
determining second page LLRs based at least in part on the second plurality of reads and known data values.
